(19) United States
(12) Patent Application Publication
(10) Pub. No.: US 2009/0194807 A1
(43) Pub. Date: Aug. 6, 2009

(54) SEMICONDUCTOR MEMORY DEVICE AND METHOD FOR MANUFACTURING THE SAME

(76) Inventors: Wakako Takeuchi, Yokohama-Shi (JP); Hiroshi Akahori, Yokohama-Shi (JP); Hiroki Yamashita, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/870,839

(22) Filed: Oct. 11, 2007

(30) Foreign Application Priority Data
Oct. 12, 2006 (JP) 2006-278695

(51) Int. Cl. H01L 29/792; H01L 21/762

(52) U.S. Cl. 257/324; 438/435; 257/E29.309; 257/E21.546

(57) ABSTRACT

A semiconductor memory device includes: a semiconductor substrate; an element isolation trench formed on the semiconductor substrate so as to surround an element region in which a memory element is to be formed; a first gate insulating film formed on the element region of the semiconductor substrate; a charge storing layer formed on the first gate insulating film; a second gate insulating film formed on the charge storing layer; a control electrode formed on the second gate insulating film; an impurity diffusion layer formed in a surface layer of the semiconductor substrate along a channel direction of the charge storing layer; a sidewall oxide film formed on a side surface of the element isolation trench; and an element isolation insulating film formed so as to fill the element isolation trench together with the element isolation insulation film; wherein the top surface of the sidewall oxide film is flush with or above the top surface of the first gate insulating film.

### CROSS REFERENCE TO RELATED APPLICATIONS

This application claims benefit of priority under 35USC S119 to Japanese patent applications No. 2006-278695, filed on Oct. 12, 2006, the contents of which are incorporated by reference herein.

### BACKGROUND OF THE INVENTION

1. Field of the Invention

The present invention relates to a semiconductor memory device and a method for manufacturing the semiconductor memory device and is directed to a NAND EEPROM, for example.

2. Related Art

A conventional NAND flash memory technique will be described below. Drawings of the manufacturing process are omitted.

To manufacture a cell array structure of a NAND flash memory, a silicon oxide film, which functions as a tunnel oxide film, a polycrystalline silicon film, which functions as a floating gate, and a silicon nitride film are formed on a silicon substrate in this order by patterning using a resist and photolithography, an oxide film is formed on the inner wall of an element isolation trench formed in the silicon substrate, a buried insulating film is deposited, and then the height of the buried insulating film is reduced by wet etching. This conventional technique has a problem that the oxide film on the inner wall of the element isolation trench is etched to expose the side surfaces of the silicon oxide film which functions as a tunnel oxide film, and a subsequent post oxide film process can often result in bird's beak (see FIG. 6) in the exposed silicon oxide film. Another problem with this technique is that the etching can remove the side surface of the silicon oxide film which functions as the tunnel oxide film (see FIG. 5), causing degradation of characteristics of the tunnel oxide film.

To solve the problems, an approach has been proposed that covers the inner wall of an element isolation trench formed in a silicon substrate with an oxynitride film (for example Japanese Patent Laid-Open (kokai) No. 2001-15618).

However, this approach has a problem that, because the inner wall of the element isolation trench is directly covered with the oxynitride film, a fixed charge is generated between the oxynitride film and silicon on the sidewall, degrading the performance of a transistor.

### SUMMARY OF THE INVENTION

According to a first aspect of the invention, there is provided a semiconductor memory device, comprising:

a semiconductor substrate;

an element isolation trench formed on the semiconductor substrate so as to surround an element region in which a memory element is to be formed;

a first gate insulating film formed on the element region of the semiconductor substrate;

a charge storing layer formed on the first gate insulating film;

a second gate insulating film formed on the charge storing layer;

a control electrode formed on the second gate insulating film;

an impurity diffusion layer formed in a surface layer of the semiconductor substrate along a channel direction of the charge storing layer;

a sidewall oxide film formed on a side surface of the element isolation trench; and

an element isolation insulating film formed so as to fill the element isolation trench together with the element isolation insulation film;

wherein the top surface of the sidewall oxide film is flush with or above the top surface of the first gate insulating film.

According to a second aspect of the invention, there is provided a method of manufacturing a semiconductor memory device, comprising:

forming a polycrystalline silicon layer on a first insulating film on a semiconductor substrate;

selectively removing the polycrystalline silicon layer, the first insulating layer, and the semiconductor substrate to form a charge storing layer and a first gate insulating film and forming in the semiconductor substrate an element isolation trench which has a bottom in the semiconductor substrate and surrounds an element region in which a memory element is to be formed;

forming a sidewall oxide film on a side surface of the element isolation trench;

nitriding a surface of the sidewall oxide film on a side opposite to the semiconductor substrate side;

filling the element isolation trench with a second insulating film together with the sidewall oxide film;

selectively removing the second insulating film and the sidewall oxide film to form an element isolation insulating film;

forming a second gate insulating film on the charge storing layer;

forming a control electrode on the second gate insulating film; and

forming an impurity diffusion layer in the surface layer of the semiconductor substrate along a channel direction of the charge storing layer.

### BRIEF DESCRIPTION OF THE DRAWINGS

In the accompanying drawings:

FIG. 1 is a top view schematically showing a configuration of a semiconductor memory device according to one embodiment of the present invention;

FIG. 2 is a circuit diagram of the semiconductor memory device shown in FIG. 1;

FIG. 3 is a cross-sectional view of the semiconductor memory device taken along line B-B in FIG. 1;

FIG. 4 is a cross-sectional view of the semiconductor memory device taken along line A-A in FIG. 1;

FIG. 5 is a diagram showing an example of overetching that occurred at an end of tunnel oxide film in a conventional technique;

FIG. 6 is a diagram showing an example of bird's beak that occurred in a tunnel oxide film in a conventional technique;

FIG. 7 is a cross-sectional view showing a variation of the semiconductor memory device shown in FIG. 1;

FIGS. 8 to 12 are schematic cross-sectional views taken along line B-B, illustrating a method for manufacturing the semiconductor memory device shown in FIG. 1;

FIG. 13 is a graph for explaining the concentration of nitrogen required in a process for nitriding a sidewall oxide film;

FIGS. 14 to 17 are schematic cross-sectional views taken along line B-B, illustrating a method for manufacturing the semiconductor memory device shown in FIG. 1; and

FIG. 18 is a schematic cross-sectional view taken along line A-A, illustrating a method for manufacturing the semiconductor memory device shown in FIG. 1.

### DETAILED DESCRIPTION OF THE INVENTION

An embodiment of the present invention will be described below with reference to the drawings.

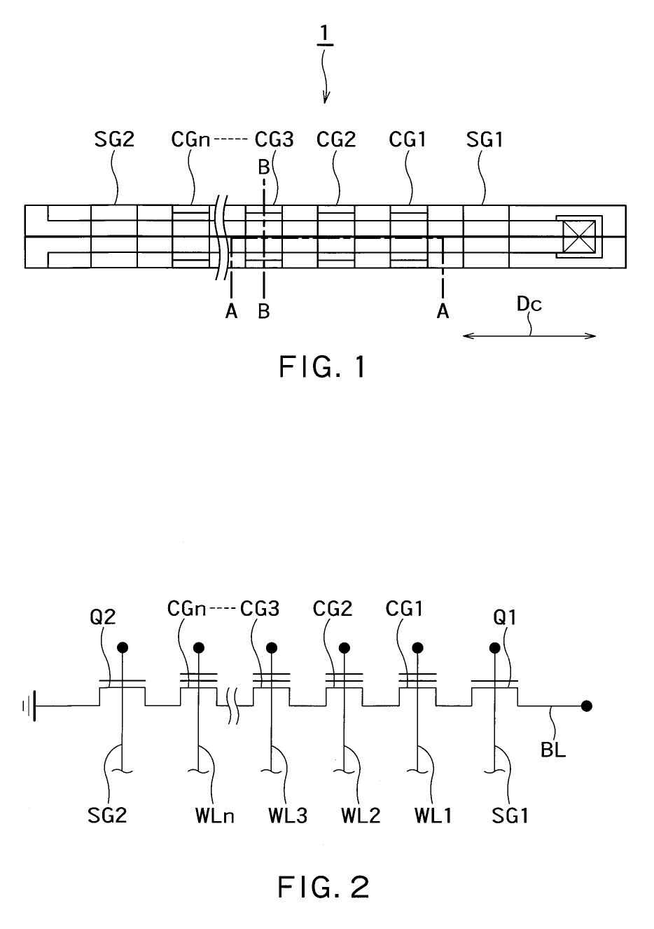

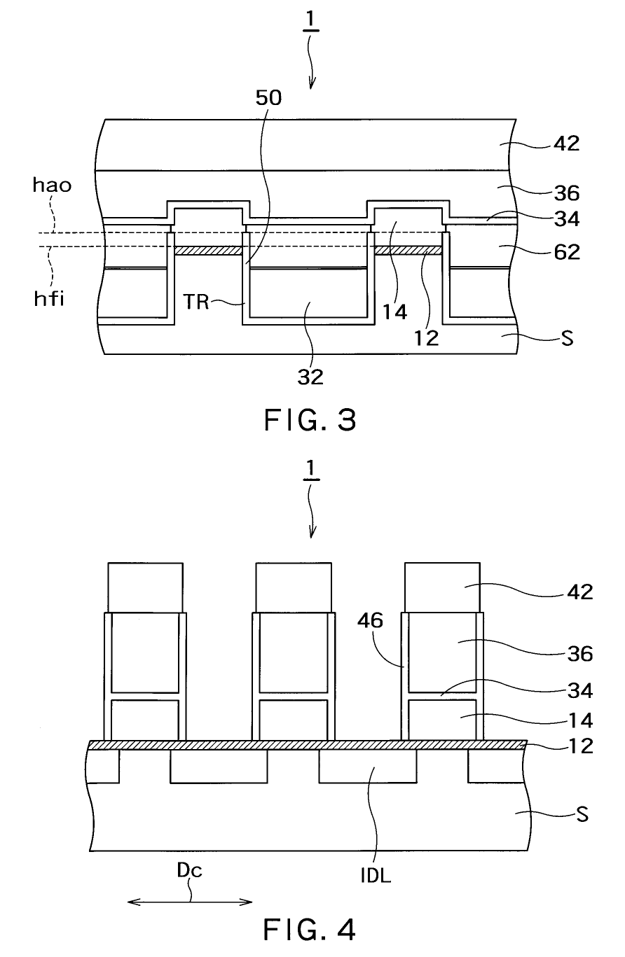

FIG. 1 is a top view schematically showing a configuration of a semiconductor memory device according to one embodiment of the present invention and FIG. 2 is a circuit diagram of the semiconductor memory device shown in FIG. 1.

The semiconductor memory device 1 shown in FIG. 1 is a part of a non-volatile semiconductor memory device having a cell array structure of a NAND flash memory that includes multiple cell transistors CG1 to CGn, which are n-channel MISFETs (Metal Insulator Semiconductor Field Effect Transistors) and selecting n-channel MISFETs Q1 and Q2 formed on the surface layer or in the same well (not shown) of a semiconductor substrate.

The cell transistors CG1 to CGn each having a floating gate and a control gate, are connected in series. The drain at one end of the cell transistors CG1 to CGn is connected to a bit line BL through selecting MISFET Q1. The source at the other end of the cell transistors CG1 to CGn is connected to a source line through selecting MISFET Q2. Although not shown in FIGS. 1 and 2 for simplicity of description, the series-connected cell transistors CG1 to CGn and selecting transistors Q1 and Q2 are formed repeatedly in the vertical direction on the sheet plane of FIG. 1 to form a cell array.

The control electrode of selecting MISFET Q1 is connected to a selection line SG1, the control electrodes of the cell transistors CG1 to CGn are connected to word lines WL1 to WLn, respectively, and the control electrode of selecting MISFET Q2 is connected to a selection line SG2. One end of each of the word lines WL1 to WLn has a connection pad (not shown) for connecting to a peripheral circuit (not shown) through a metal wire, not shown, and is formed on an element isolation film.

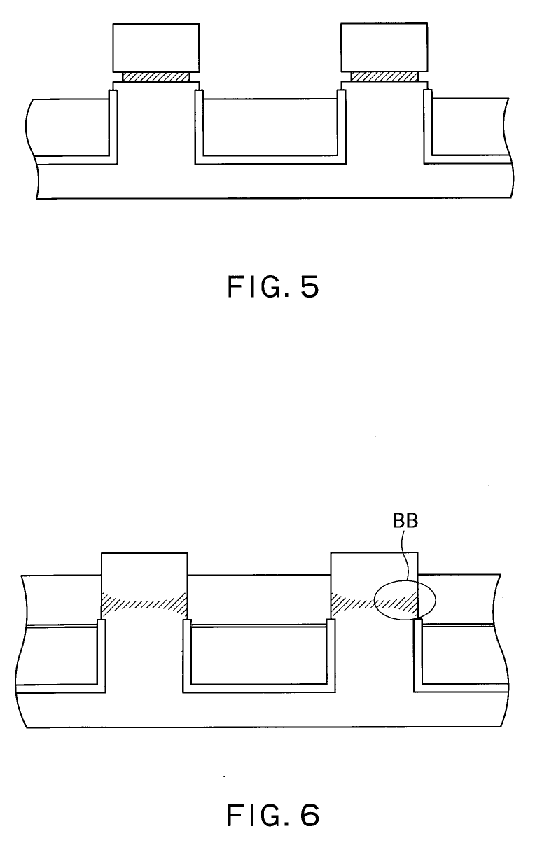

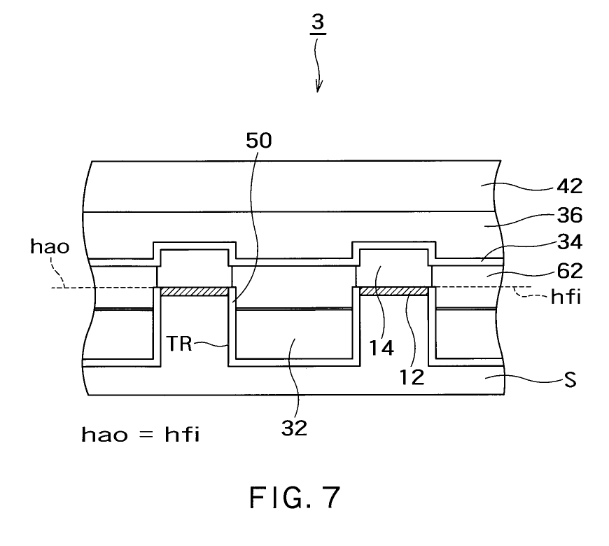

FIG. 3 shows a cross-sectional view of the semiconductor memory device taken along line B-B in FIG. 1 and FIG. 4 shows a cross-sectional view of the semiconductor memory device taken along line A-A in FIG. 1.

As shown in the cross-sectional view in FIG. 3, the semiconductor memory device 1 includes a semiconductor substrate S in which element isolation trenches TR are formed, a tunnel oxide film 12 formed on an element region of the semiconductor substrate S, floating gates 14 formed on the tunnel oxide film 12, a second gate insulation film 34 formed on the floating gates 14, and control gates 36 formed on the second gate insulation film 34. A sidewall oxide film 50, which is characteristic in the present embodiment, is formed on the bottom and side surfaces of the element isolation trench TR. An element isolation insulating film 32 is formed in such a manner that the element isolation trench TR is filled with the element isolation insulating film 32 with the sidewall oxide film 50 being between the element isolation trench TR and the element isolation insulating film 32. The tunnel oxide film 12 in the present embodiment is equivalent to a first gate insulating film, for example, and the floating gate 14 is equivalent to a charge storing layer, for example. The control gate 36 in the present embodiment is equivalent to a control electrode, for example.

Referring to the cross-sectional view of FIG. 4, the semiconductor memory device 1 includes an impurity diffusion layer IDL formed in the surface layer of the semiconductor substrate S along the channel direction Dc of the charge storing layer. A nitride film 42 formed as a mask for selectively removing the control gate 36, the second gate insulating film 34, and the charge storing layer 14 in the manufacturing process remains on the control gate 36.

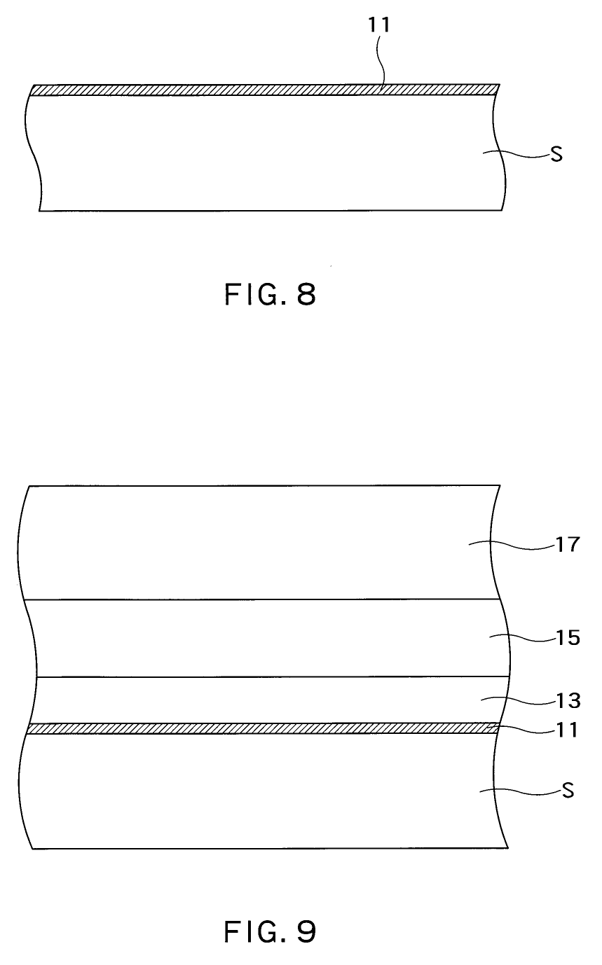

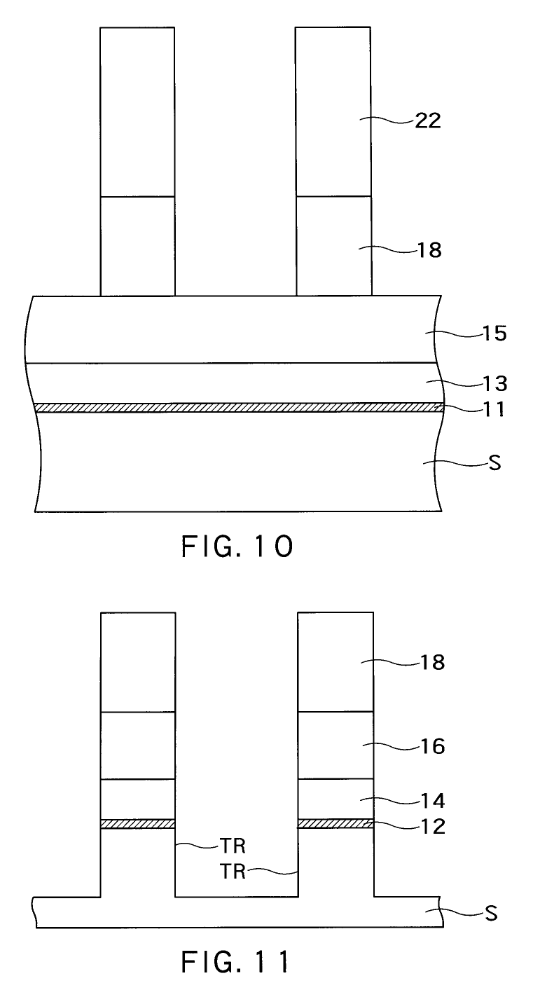

As can be seen from FIG. 3, the sidewall oxide film 50 in the present embodiment is formed so that the height “hao” of the top surface is positioned higher than the height “hfi” of the top surface of the tunnel oxide film 12. As a result, the side surface of the tunnel oxide film 12 is covered with the sidewall oxide film 50, which prevents overetching (see FIG. 5) of the tunnel oxide film 12 which would occur in the conventional techniques. This can also prevent bird's beak (the geometry in the portion labeled with symbol BB in FIG. 6) that would occur in the tunnel oxide film 12 in a post-oxidation process in the conventional techniques.

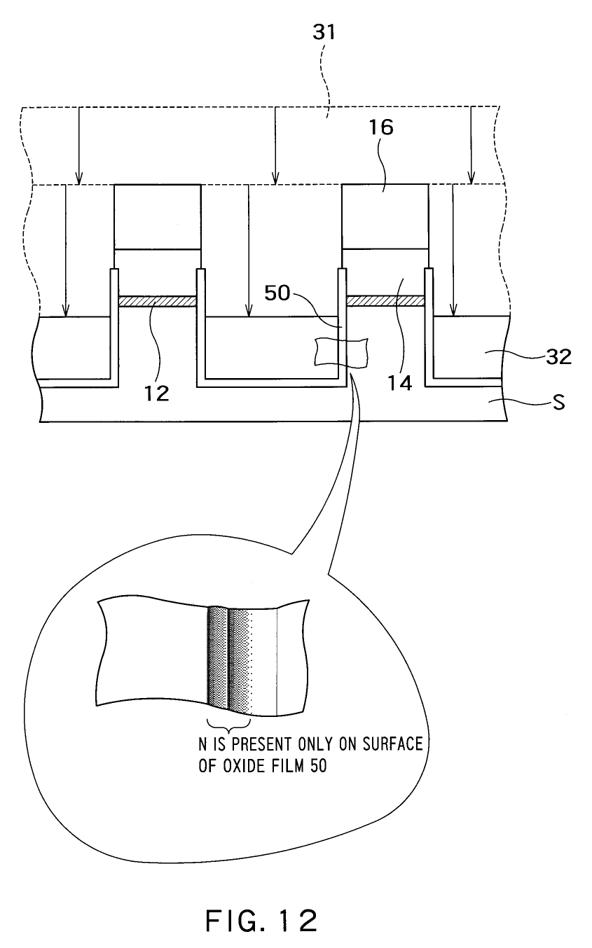

The present invention is not limited to the mode shown in FIG. 3. Since the side surface of the tunnel oxide film 12 is covered with the sidewall oxide film 50 unless the height “hao” of the top surface of the sidewall oxide film 50 is lower than the height “hfi” of the top surface of the tunnel oxide film 12, the height “hao” of the top surface of the sidewall oxide film 50 may be the same as the height “hfi” of the tunnel oxide film 12 as in a variation 3 shown in FIG. 7.

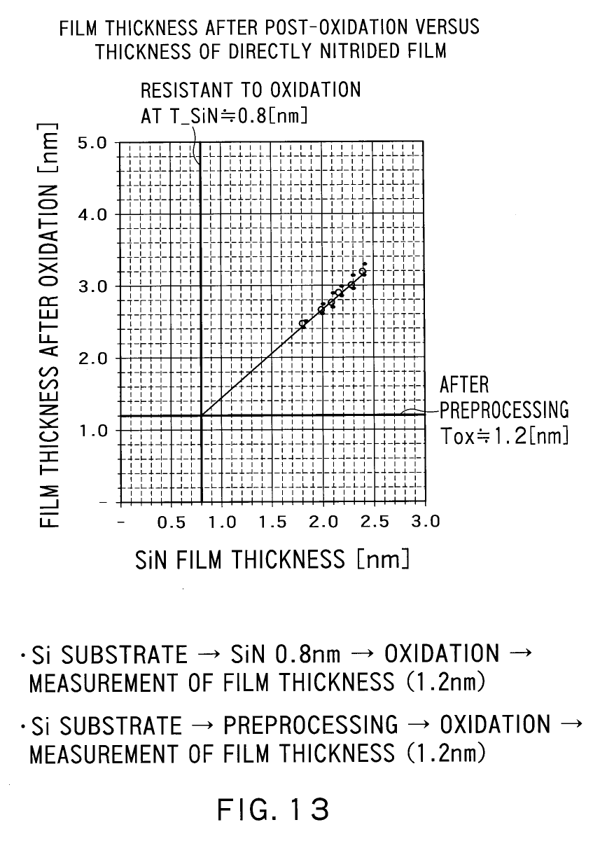

A method for manufacturing the semiconductor memory device shown in FIG. 1 will be described with reference to FIGS. 8 to 18.

First, a silicon oxide film 11, which functions as a tunnel oxide film, is formed on a semiconductor substrate S such as a silicon substrate by using a thermal oxide film method, as shown in FIG. 8. The silicon oxide film 11 in the present embodiment is equivalent to a first insulating film, for example.

Then, a polycrystalline silicon film 13, a silicon nitride film 15, and an oxide film 17 are deposited on the silicon oxide film 11 using a CVD (Chemical Vapor Deposition) method, for example, as shown in FIG. 9. The polycrystalline silicon film 13 will be processed into a floating gate 14 through a process which will be described later.

Subsequently, a photoresist is applied as shown in FIG. 10, and then a resist film 22 is formed by patterning using photolithography and is used as a mask to selectively remove the oxide film 17 to form an oxide film 18. The resist film 22 is removed and then the oxide film 18 is used as a mask to remove the silicon nitride film 15, polycrystalline silicon film 13, silicon oxide film 11, and semiconductor substrate S in a self-aligned manner. As a result, a tunnel oxide film 12, floating gate 14, and silicon nitride film 16 are formed in the direction perpendicular to the channel direction Dc, and an element isolation trench TR surrounding an element region where a memory element will be formed is formed in the semiconductor substrate S as shown in FIG. 11. Then, an oxide film is deposited using a thermal oxidation method or an LP (Low Pressure) CVD method to form an oxide film 50 on the entire surface of the element isolation trench TR and then only the surface of the oxide film 50 is nitrided using plasma or radical nitriding species, as shown in a partially enlarged view in FIG. 12. The following method may be used for the nitriding.

A mixed gas of nitrogen (N₂) and argon (Ar) is flowed into a chamber into which a microwave can be introduced and the mixed gas is irradiated with a microwave to generate plasma. Nitrogen radicals contained in the plasma are supplied onto the semiconductor substrate S to nitride the surface of the sidewall oxide film 50. The temperature at which the nitrogen radicals are supplied is in the range from approximately 200 to approximately 700 degrees C., preferably in the range from 400 to 500 degrees C. In this example, the irradiation is performed at a temperature at which surface nitriding by heat energy does not occur. This is because nitriding by heat energy produces the side effect of anomalously diffusing dopant for forming wells and channels in the semiconductor substrate S. This side effect can be avoided by radical low temperature nitriding.

Thus, according to the present embodiment, by covering the inner wall of the element isolation trench TR with the oxide film 50 and nitriding the surface of the oxide film 50, a good interface having a low fixed charge density can be maintained between silicon of the semiconductor substrate S and the sidewall oxide film 50 at the side surface of the element isolation trench TR. Furthermore, the presence of the silicon nitride layer on the surface of the sidewall oxide film 50 can prevent an oxidizing agent from entering the semiconductor substrate S, thereby inhibiting formation of bird's beak.

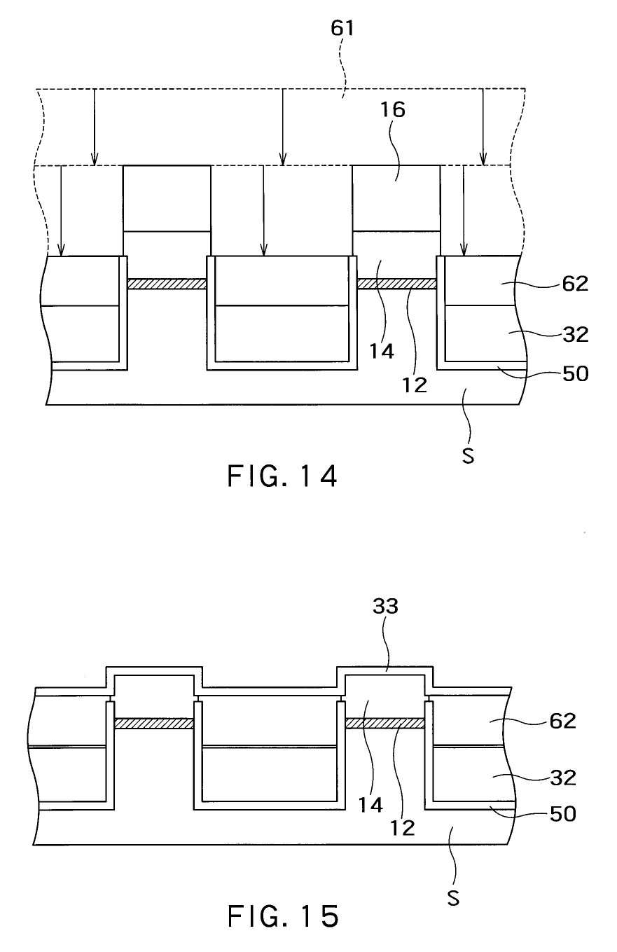

The nitride density in the silicon nitride layer on the surface of the sidewall oxide film 50 is adjusted to a value such that overetching to the sidewall oxide film 50 itself is prevented and the top surface of the sidewall oxide film 50 remains at a position higher than the top surface of the tunnel oxide film 12 in the wet etching process for lowering the heights of a buried insulating film 3 and an insulating material 61, which will be described later. Preferably, the value of the nitride density of the silicon nitride layer on the surface of the sidewall oxide film 50 is specifically 1E15 atoms/cm² or higher. The reason will be described with reference to FIG. 13.

FIG. 13 is a graph of the relation between the thickness of a nitride film formed on the silicon substrate and the thickness of an oxide film formed on the silicon substrate after preprocessing. It can be seen from FIG. 13 that the thickness of the film resulting from oxidation of a 0.8-nm-thick nitride film is equivalent to the thickness of the oxide film resulting from preprocessing and oxidation of the silicon substrate, that is, 1.2 nm, and that after the thickness of the nitride film reaches 0.8 nm, the relation between the thickness of the nitride film and the thickness of the oxide film after preprocessing is substantially linear. This shows that, in order to make the film thickness of a sample resulting from oxidation of a nitride film formed equal to the film thickness of a sample that underwent preprocessing and oxidation (1.2 nm), a 0.8-nm-thick nitride film is required as given below.

silicon substrate→SiN(0.8 nm)→oxidation→measurement of film thickness (1.2 nm)

silicon substrate→preprocessing→oxidation→measurement of film thickness (1.2 nm)

Since the density of the nitride film (Si₃N₄=140) is 3 g/cm³=3×6.02E23/140=1.29E22 atoms/cm³, the density of nitrogen required in the present embodiment is

1.29E22 atoms/cm³×0.8E−7 cm=1.0E15 atoms/cm²

Returning to FIG. 12, a buried insulating film 31 is deposited on the entire surface by plasma CVD, for example, and is planarized by polishing down to the silicon nitride film 16 by CMP, for example, and then is etched to a level lower than the tunnel oxide film 12 by wet etching to form an element isolation insulating film 32. Because the surface of the sidewall oxide film 50 nearer to the buried insulating film 31 has been nitrided by the surface nitriding process described above, the sidewall oxide film 50 is not excessively removed and the top surface of the sidewall oxide film 50 remains at a position higher than the top surface of the tunnel oxide film 12. The buried insulating film 31 in the present embodiment is equivalent to a second insulating film, for example.

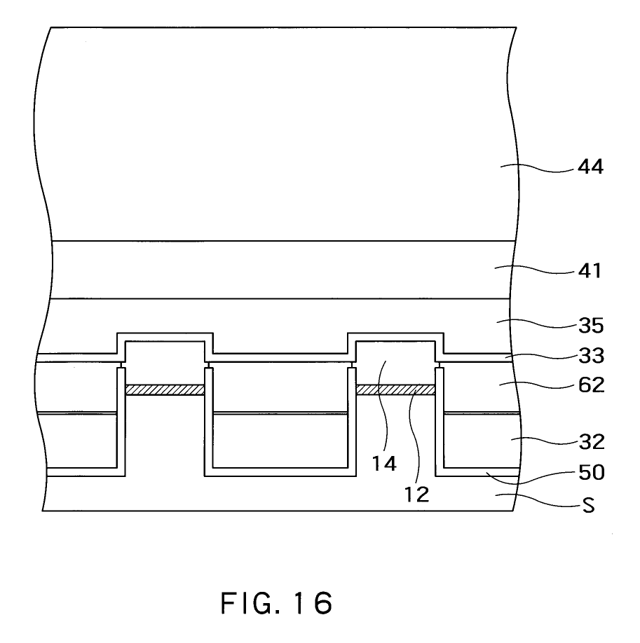

Then, as shown in FIG. 14, an insulating material 61 that differs from the material of the element isolation insulating film 32 is deposited on the entire surface, is polished to the silicon nitride film 16 and planarized by CMP, for example, and then the insulating material 61 is wet-etched to lower its height to form a buried insulating film 62. Since the surface of the sidewall oxide film 50 nearer to the insulating material 61 has been nitrided by the surface nitriding process described above, the sidewall oxide film 50 is not excessively removed and its top surface remains at a position higher than the top surface of the tunnel oxide film 12. Then wet processing is performed to strip the silicon nitride film 16.

An insulating film 33 is formed on the entire surface of the element isolation structure formed by the above-described process (FIG. 15). Then a polycrystalline silicon film 35 is formed on the insulating film 33 by using LPCVD, for example. The insulating film 33 will be processed into a second gate insulating film 34 in a subsequent process. The polycrystalline silicon film 35 is processed into a control gate 36 in a subsequent process.

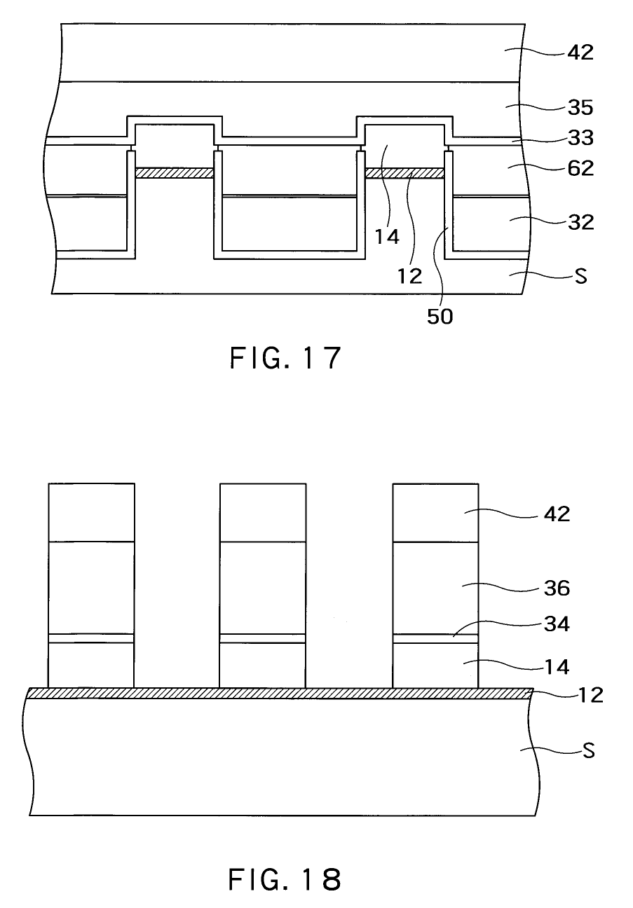

Then, silicon nitride film 41 is formed on the polycrystalline silicon film 35 by LPCVD, for example, and then a photoresist is applied to the silicon nitride film 41. The photoresist is patterned into a predetermined geometry by using photolithography to form a photoresist 44. The photoresist 44 is used as a mask to selectively remove the silicon nitride film 41 (in frontward and rearward regions in the direction perpendicular to the sheet plane of FIG. 16) to form a silicon nitride film 42 (see FIG. 18).

Subsequently, the photoresist 44 is removed and then the silicon nitride 42 is used as a mask to etch as shown in FIG. 17 to selectively remove the polycrystalline silicon film 35 (control gate 36), insulating film 33 (second gate insulating film 34), and polycrystalline silicon film 13 (floating gate 14) in this order (in frontward and rearward regions in the direction perpendicular to the sheet plane of FIG. 17). The resulting cross-sectional view taken along line A-A of FIG. 1 is shown in FIG. 18.

Then a silicon oxide film 46 is formed on the side surfaces of the polycrystalline silicon film 35 (control gate 36), insulating film 33 (second gate insulating film 34), and polycrystalline silicon film 13 (floating gate 14) (see FIG. 4) in the direction of the bit line by thermal oxidation. This oxidation process is generally called the post-oxidation process and the polycrystalline silicon oxide film 46 formed by the post-oxidation process is called the post-oxidation film. The purposes of forming such a post-oxidation film 46 are to minimize leak current at the gate end, to improve the surface pressure resistance of high-voltage peripheral circuit MISFETs, that is, the pressure resistance of the gate insulating film, and to restore damage introduced to the gate oxide film through a gate electrode by RIE (Reactive Ion Etching).

After the post-oxidation film 46 is formed, an impurity diffusion layer IDL, which functions as a source and drain, is formed by ion implantation and thermal annealing to form a memory transistor, thus providing the semiconductor memory device 1 shown in FIG. 4.

As has been described, according to the present embodiment, overetching to the sidewall oxide film 50 itself during the wet etching process for lowering the heights of the buried insulating film 31 and the insulating material 61 can be prevented by nitriding only the surface of the sidewall oxide film 50. As a result, the side surface of the tunnel oxide film 12 is covered with the sidewall oxide film 50 (see FIGS. 12 and 7), which not only can prevent the tunnel oxide film 12 from being etched but also can minimize bird's beak during the post-oxidation process. Furthermore, since nitrogen does not enter the semiconductor substrate S, the possibility of variation in thresholds for cell transistors and selecting transistors can be eliminated.

While one embodiment of the present invention has been described, the present invention is not limited to the embodiment described above. It will be understood that various modifications can be made within the technical scope of the present invention. For example, while only the surface of the sidewall oxide film 50 is nitrided by plasma nitriding in the embodiment described above, the present invention is not so limited. Any method that allows nitrogen to remain only on the surface of the sidewall oxide film and prevents nitrogen from reaching the semiconductor substrate S can be used. For example, a thin nitride film may be formed after the sidewall oxide film 50 is formed.

What is claimed is:

1. A semiconductor memory device, comprising:
a semiconductor substrate;
an element isolation trench formed on the semiconductor substrate so as to surround an element region in which a memory element is to be formed;
a first gate insulating film formed on the element region of the semiconductor substrate;
a charge storing layer formed on the first gate insulating film;
a second gate insulating film formed on the charge storing layer;
a control electrode formed on the second gate insulating film;
an impurity diffusion layer formed in a surface layer of the semiconductor substrate along a channel direction of the charge storing layer;
a sidewall oxide film formed on a side surface of the element isolation trench; and
an element isolation insulating film formed so as to fill the element isolation trench together with the element isolation insulation film;
wherein the top surface of the sidewall oxide film is flush with or above the top surface of the first gate insulating film.

2. The semiconductor memory device according to claim 1,
wherein the surface of the sidewall oxide film is nitrided on a side opposite to the semiconductor substrate side.

3. The semiconductor memory device according to claim 1, further comprising a post-oxidation film formed on each side surface of the charge storing layer, the second gate insulating film and the control electrode in a direction of a bit line.

4. The semiconductor memory device according to claim 2, wherein the concentration of nitrogen in the surface of the sidewall oxide film on the side opposite to the semiconductor substrate side is equal to or higher than 1E15 atoms/cm².

5. The semiconductor memory device according to claim 4, further comprising a post-oxidation film formed on each side surface of the charge storing layer, the second gate insulating film and the control electrode in a direction of a bit line.

6. A method of manufacturing a semiconductor memory device, comprising:
forming a polycrystalline silicon layer on a first insulating film on a semiconductor substrate;
selectively removing the polycrystalline silicon layer, the first insulating layer, and the semiconductor substrate to form a charge storing layer and a first gate insulating film and forming in the semiconductor substrate an element isolation trench which has a bottom in the semiconductor substrate and surrounds an element region in which a memory element is to be formed;
forming a sidewall oxide film on a side surface of the element isolation trench;
nitriding a surface of the sidewall oxide film on a side opposite to the semiconductor substrate side;
filling the element isolation trench with a second insulating film together with the sidewall oxide film;
selectively removing the second insulating film and the sidewall oxide film to form an element isolation insulating film;
forming a second gate insulating film on the charge storing layer;
forming a control electrode on the second gate insulating film; and
forming an impurity diffusion layer in the surface layer of the semiconductor substrate along a channel direction of the charge storing layer.

7. The method of manufacturing a semiconductor memory device according to claim 6,
wherein the surface of the sidewall oxide film on the side opposite to the semiconductor substrate side is nitrided so that the surface has a nitrogen concentration of 1E15 atoms/cm² or higher.

8. The method of manufacturing a semiconductor memory device according to claim 6,
wherein the surface of the sidewall oxide film on the side opposite to the semiconductor substrate side is nitrided by plasma nitriding.

9. The method of manufacturing a semiconductor memory device according to claim 6,
wherein the surface of the sidewall oxide film on the side opposite to the semiconductor substrate side is nitrided by forming a thin nitride film on the formed sidewall oxide film.

10. The method of manufacturing a semiconductor memory device according to claim 6, further comprising forming a post-oxidation film on each side surface of the charge storing layer, the second gate insulating film and the control electrode in a direction of a bit line.
